(19) United States
(12) Patent Application Publication
(10) Pub. No.: US 2023/0007789 A1
(43) Pub. Date: Jan. 5, 2023

(54) PROCESS FOR APPLYING A TWO-DIMENSIONAL MATERIAL TO A TARGET SUBSTRATE POST-LAMINATION

(71) Applicants: Mellanox Technologies, Ltd., Yokneam (IL); Bar-Ilan University, Ramat Gan (IL)

(72) Inventors: Elad MENTOVICH, Tel Aviv (IL); Boaz Atias, Maale Adumim (IL); Doron Naveh, Petah-Tikva (IL); Adi Levi, Rosh HaAyin (IL)

(21) Appl. No.: 17/305,238

(22) Filed: Jul. 1, 2021

(51) Int. Cl. H05K 3/46

(52) U.S. Cl. CPC H05K 3/4644

(57) ABSTRACT

Processes for creating a two-dimensional-target structure are disclosed. An example process to create a two-dimensional-target structure may include the process of providing two-dimensional material grown on an initial substrate to create a two-dimensional-substrate structure; applying the two-dimensional-substrate structure to a target substrate via an adhesion promoter to create a lamination stack; applying a lamination process to the lamination stack; and then removing the initial substrate from the lamination stack, post-lamination, to create the two-dimensional-target structure. The two-dimensional-target structure may then be used in such rigid or flexible electronic devices and/or non-standard devices as the target substrate may be rigid or flexible and/or translucent in contrast to the initial substrate first used to grow the two-dimensional material.

### TECHNOLOGICAL FIELD

Embodiments of the present invention relate generally to processes for applying a two-dimensional material to a target substrate using an initial substrate that includes the two-dimensional material.

### BACKGROUND

A two-dimensional (2D) material—which may be grown on a substrate—may require high heat and/or pressurization to be transferred from its initial substrate (e.g., the substrate the 2D material was grown) to a target (e.g., destination or receiving) substrate. In some embodiments, this high heat and/or pressurization to transfer the two-dimensional material may cause breakage, tearing, melting, or other such deformities on the target substrate and/or two-dimensional material if the target substrate is made of a material that does not support the temperatures and pressures needed to grow or form the two-dimensional material. At the same time, the demand for conductive, rigid or flexible, and/or translucent properties for non-standard electronic devices is growing, and the target substrates used in such non-standard electronic devices may not have the properties needed to support conventional methods for forming the two-dimensional materials (e.g., the properties like that of the initial substrates). Further, known processes to form such two-dimensional-target substrates similar to that described herein may not comprise a uniform thickness as the two-dimensional material may be applied to the target substrate by adding flakes individually. Instead, the invention described herein overcomes the deficiencies of the prior art by reciting a process and product to create a two-dimensional-target substrate comprising rigid or flexible, transparent, and/or uniform in thickness properties.

A two-dimensional material, when applied to certain target substrates, may provide such properties as insulation, high conductibility, and high frequency, for the target substrates. For example, a target substrate may comprise a rigid or flexible and/or translucent material comprising conductive material (e.g., semiconductor wafers, polymers, or any other conductive rigid or flexible material known in the art). Further, in some embodiments, the two-dimensional material may first be grown on an initial substrate comprising a high melting point threshold, such that the two-dimensional material may be grown on the initial substrate and then placed on a target substrate comprising different properties from the initial substrate. Such removal process may allow the two-dimensional material to be extracted from the initial substrate without damage, tearing, or breakage. According to embodiments of the invention described herein, the target substrate comprising the two-dimensional material may be used in rigid or flexible and/or semi-translucent/translucent electronic devices.

### BRIEF SUMMARY

Embodiments of the present invention provide an improved process for creating two-dimensional-target structures to be used in rigid or flexible and/or semi-translucent/translucent electronic devices. The improvements provided by embodiments of the present invention further include an improved process for placing a two-dimensional material onto a target substrate and then removing an initial substrate (e.g., used to grow the two-dimensional material) from the lamination stack of materials comprising the target substrate, two-dimensional material, initial substrate, and—in some embodiments—an adhesion promoter.

In some embodiments, the process for laminating graphene-coated printed circuit boards may include an apparatus to apply each of the materials discussed in further detail below and carry out the processes herein described. An example apparatus may include a continuous-feed CVD system described in the application titled, CONTINUOUS-FEED CHEMICAL VAPOR DEPOSITION SYSTEM, Ser. No. ______, filed concurrently with the present application and the contents of which are hereby incorporated by reference in their entirety. Further, in some embodiments, the continuous-feed CVD system may include a substrate carrier and associated mechanisms for moving the lamination stack and printed circuit board through the continuous-feed CVD system, such as the substrate carrier and associated mechanisms described in the application titled, CVD SYSTEM WITH SUBSTRATE CARRIER AND ASSOCIATED MECHANISMS FOR MOVING SUBSTRATE THERETHROUGH, Ser. No. ______, filed concurrently with the present application and the contents of which are hereby incorporated by reference in their entirety. Further, in some embodiments, the continuous-feed CVD system may include components configured for facilitating uniform and laminar flow, such as the components described in the application titled, CVD SYSTEM WITH FLANGE ASSEMBLY FOR FACILITATING UNIFORM AND LAMINAR FLOW, Ser. No. ______, filed concurrently with the present application and the contents of which are hereby incorporated by reference in their entirety.

In some embodiments, he process for applying a two-dimensional material to a target substrate post-lamination may include the process for creating the graphene-coated lamination stack and printed circuit board, such as the method and product described in the application titled, PROCESS FOR LAMINATING GRAPHENE-COATED PRINTED CIRCUIT BOARDS, Ser. No. ______, filed concurrently with the present application and the contents of which are hereby incorporated by reference in their entirety. Further, in some embodiments, the process for applying a two-dimensional material to a target substrate post-lamination may include the process for repairing the graphene-coated lamination stack and printed circuit board, such as the materials and processes described in the application titled, PROCESS FOR LOCALIZED REPAIR OF GRAPHENE-COATED LAMINATION STACKS AND PRINTED CIRCUIT BOARDS, Ser. No. ______, filed concurrently with the present application and the contents of which are hereby incorporated by reference in their entirety. Further, in some embodiments, the process for applying a two-dimensional material to a target substrate post-lamination include the materials and processes including the material of hexagonal Boron Nitride (h-BN) as an alternative coating to the lamination stack and printed circuit board and methods for doping and removing structures within the lamination stacks and printed circuit boards, such as the materials and processes described in the application titled, PROCESS FOR LAMINTATING CONDUCTIVE-LUBRICANT COATED METALS FOR PRINTED CIRCUIT BOARDS, Ser. No. ______, filed concurrently with the present application and the contents of which are hereby incorporated by reference in their entirety.

A two-dimensional material, when applied to certain target substrates, may provide such properties as insulation, high conductibility, and high frequency, for the target substrates. For example, a target substrate may comprise a rigid or flexible and/or translucent material comprising conductive material (e.g., semiconductor wafers, polymers, or any other conductive rigid or flexible material known in the art). Further, in some embodiments, the two-dimensional material may first be grown on an initial substrate comprising a high melting point threshold, such that the two-dimensional material may be grown on the initial substrate and then placed on a target substrate comprising different properties from the initial substrate. Such removal process may allow the two-dimensional material to be extracted from the initial substrate without damage, tearing, or breakage. According to embodiments of the invention described herein, the target substrate comprising the two-dimensional material may be used in such rigid or flexible and/or semi-translucent/translucent electronic devices.

Accordingly, example embodiments of the present invention relate generally to system(s), methods and apparatuses to provide an improved process for two-dimensional materials placed on a target substrate to form a two-dimensional-target structure. The details of some embodiments of the subject matter described in this specification are set forth in the accompanying drawings and the description below. Other features, aspects, and advantages of the subject matter will become apparent from the description, the drawings, and the claims.

In accordance with some embodiments of the present invention, a method of applying a two-dimensional material to a target substrate is provided, wherein the method comprises providing a target substrate; applying an adhesion promoter to a surface of the target substrate; applying a two-dimensional-substrate structure to the surface of the target substrate via the adhesion promoter to form a lamination stack, wherein the two-dimensional-substrate structure comprises an initial substrate layer and a two-dimensional material on at least one of a top surface of the initial substrate layer or a bottom surface of the initial substrate layer; applying a heat and a pressure to the lamination stack; and removing the initial substrate layer from the lamination stack, after the heat and the pressure are applied, to form a two-dimensional-target structure.

In accordance with another aspect of the present invention, the method of applying a two-dimensional material to a target substrate further comprises applying a heat and a pressure to the two-dimensional-target structure.

In accordance with another aspect of the present invention, the method of applying a two-dimensional material to a target substrate may include the embodiment wherein the two-dimensional material comprises hexagonal Boron Nitride (h-BN), graphene, black phosphorus, black arsen-phosphorus, mxene, two-dimensional perovskites, or any combination thereof.

In accordance with another aspect of the present invention, the method of applying a two-dimensional material to a target substrate includes the embodiment wherein the adhesion promoter layer comprises epoxy resin, polyester, silicone, rubber, polysulfides, polypropylene, polyethylene, polyurethane, polydimethylsiloxane (PDMS), polyimide (PI), parylene, polyetherimide (PEI), polyamide (PA), polylactic acid (PLA), hydrocarbon-based film adhesive, Kapton, self-assembled monolayer (SAM), parylen, polyvinyl alcohol PVA, Polystyrene PS, Polycarbonate (PC), cellulose acetate (CA), ethylene vinyl acetate (EVA), or any combination thereof.

In accordance with another aspect of the present invention, the method of applying a two-dimensional material to a target substrate may include the embodiment wherein the initial substrate layer comprises nickel (Ni), copper (Cu), platina (Pt), cobalt (Co), chromium (Cr), iridium (Ir), manganese (Mn), iron (Fe), tungsten (W), silver (Ag), ruthenium (Ru), rhodium (Rh), gold (Au), molybdenum (Mo), palladium (Pd), gallium (Ga), Indium (In), tin (Sn), silicon (Si), silicon dioxide (SiO2), mica, sapphire, polymeric liquid glass, glass substrate, AI₂O₃ metals, hafnium, or any combination thereof.

In accordance with another aspect of the present invention, the method of applying a two-dimensional material to a target substrate may include the embodiment wherein the target substrate comprises at least a semiconductor or other solid wafer.

In accordance with another aspect of the present invention, the method of applying a two-dimensional material to a target substrate may include the embodiment wherein the semiconductor wafer comprises silicon (Si), germanium (Ge), II-VI compound, III-V compound, glass, sapphire, quartz, or any combination thereof.

In accordance with another aspect of the present invention, the method of applying a two-dimensional material to a target substrate may include the embodiment wherein the target substrate comprises a polymer.

In accordance with another aspect of the present invention, the method of applying a two-dimensional material to a target substrate may include the embodiment wherein the polymer comprises polyethylene terephthalate (PET), polydimethylsiloxane (PDMS), polytetrafluoroethylene (PTFE), low density polyethylene (LDPE), nylon, ply(vinylpyrrolidone) (PVP), polystyrene (PS), poly(methyl methacrylate) (PMMA), poly(vinyl alcohol) (PVA), poly(vinyl chloride) (PVC), poly(vinylidene fluoride) (PVDF), polyalactic acid (PLA), polyimide (PI), polyetherimide (PEI), polyamide (PA), acrylonitrile butadiene styrene (ANBS), styrenic resins, kapton, silicon (Si), silicon dioxide (SiO2), thin-film metal-oxide, or any combination thereof.

In accordance with some embodiments of the present invention, a method of applying a two-dimensional material to a target substrate is provided, wherein the method comprises providing a two-dimensional-substrate structure, wherein the two-dimensional-substrate structure comprises an initial substrate layer and a two-dimensional material on at least one of a top surface of the initial substrate layer or a bottom surface of the initial substrate layer; applying an adhesion promoter to a surface of the two-dimensional-substrate structure; applying a target substrate to the surface of the two-dimensional-substrate structure via the adhesion promoter to form a lamination stack; applying a heat and a pressure to the lamination stack; and removing the initial substrate layer from the lamination stack, after the heat and the pressure are applied, to form a two-dimensional-target structure.

In accordance with some embodiments of the present invention, a method of applying a two-dimensional material to a target substrate further comprises applying a heat and a pressure to the two-dimensional-target structure.

In accordance with some embodiments of the present invention, a method of applying a two-dimensional material to a target substrate may include the embodiment wherein the two-dimensional material comprises hexagonal Boron Nitride (h-BN), graphene black phosphorus, black arsen-phosphorus, mxene, two-dimensional perovskites, or any combination thereof.

In accordance with some embodiments of the present invention, a method of applying a two-dimensional material to a target substrate may include the embodiment wherein the adhesion promoter layer comprises epoxy resin, polyester, silicone, rubber, polysulfides, polypropylene, polyethylene, polyurethane, polydimethylsiloxane (PDMS), polyimide (PI), parylene, polyetherimide (PEI), polyamide (PA), polylactic acid (PLA), hydrocarbon-based film adhesive, Kapton, self-assembled monolayer (SAM), parylen, polyvinyl alcohol PVA, Polystyrene PS, Polycarbonate (PC), cellulose acetate (CA), ethylene vinyl acetate (EVA), or any combination thereof.

In accordance with some embodiments of the present invention, a method of applying a two-dimensional material to a target substrate may include the embodiment wherein the initial substrate layer comprises nickel (Ni), copper (Cu), platina (Pt), cobalt (Co), chromium (Cr), iridium (Ir), manganese (Mn), iron (Fe), tungsten (W), silver (Ag), ruthenium (Ru), rhodium (Rh), gold (Au), molybdenum (Mo), palladium (Pd), gallium (Ga), Indium (In), tin (Sn), silicon (Si), silicon dioxide (SiO2), mica, sapphire, polymeric liquid glass, glass substrate, AI2O3 metals, hafnium, or any combination thereof.

In accordance with some embodiments of the present invention, a method of applying a two-dimensional material to a target substrate may include the embodiment wherein the target substrate comprises at least a semiconductor wafer or other solid wafer.

In accordance with some embodiments of the present invention, a method of applying a two-dimensional material to a target substrate may include the embodiment wherein the semiconductor wafer comprises silicon (Si), germanium (Ge), II-VI compound, III-V compound, glass, sapphire, quartz, or any combination thereof.

In accordance with some embodiments of the present invention, a method of applying a two-dimensional material to a target substrate may include the embodiment wherein the target substrate comprises a polymer.

In accordance with some embodiments of the present invention, a method of applying a two-dimensional material to a target substrate may include the embodiment wherein the polymer comprises polyethylene terephthalate (PET), polydimethylsiloxane (PDMS), polytetrafluoroethylene (PTFE), low density polyethylene (LDPE), nylon, ply(vinylpyrrolidone) (PVP), polystyrene (PS), poly(methyl methacrylate) (PMMA), poly(vinyl alcohol) (PVA), poly(vinyl chloride) (PVC), poly(vinylidene fluoride) (PVDF), polyalactic acid (PLA), polyimide (PI), polyetherimide (PEI), polyamide (PA), acrylonitrile butadiene styrene (ANBS), styrenic resins, or any combination thereof.

In accordance with some embodiments of the present invention, a two-dimensional-target structure is provided, wherein the two-dimensional-target structure is formed by the process comprising the steps of: providing a target substrate; applying an adhesion promoter to a surface of the target substrate; applying a two-dimensional-substrate structure to the surface of the target substrate via the adhesion promoter to form a lamination stack, wherein the two-dimensional-substrate structure comprises an initial substrate layer and a two-dimensional material on at least one of a top surface of the initial substrate layer or a bottom surface of the initial substrate layer; applying a heat and a pressure to the lamination stack; and removing the initial substrate layer from the lamination stack, after the heat and the pressure are applied, to form a two-dimensional-target structure.

### BRIEF DESCRIPTION OF THE DRAWINGS

Having thus described the disclosure in general terms, reference will now be made to the accompanying drawings, which are not necessarily drawn to scale, and wherein:

FIG. 1A is an example schematic diagram illustrating the application of the two-dimensional-substrate structure onto a target substrate via an adhesion promoter applied to the two-dimensional-substrate structure, in accordance with one or more embodiments of the present invention;

FIG. 1B is an example schematic diagram illustrating the application of the two-dimensional-substrate structure onto a target substrate via an adhesion promoter applied to the target substrate, in accordance with one or more embodiments of the present invention;

FIG. 2A is an example schematic diagram illustrating the removal of the initial substrate of the two-dimensional-substrate structure to form the two-dimensional-target structure, in accordance with other embodiments of the present invention;

FIG. 2A is an example schematic diagram illustrating the removal of the initial substrate of the two-dimensional-substrate structure to form the two-dimensional-target structure, in accordance with other embodiments of the present invention;

FIG. 3 illustrates an example flowchart of the present invention, in accordance with one or more embodiments of the present invention; and

FIG. 4 provides an example flowchart of the present invention, in accordance with one or more embodiments of the present invention.

### DETAILED DESCRIPTION

Example embodiments will now be described more fully hereinafter with reference to the accompanying drawings, in which some, but not all, embodiments are shown. Indeed, the embodiments may take many different forms and should not be construed as limited to the embodiments set forth herein; rather, these embodiments are provided so that this disclosure will satisfy applicable legal requirements. Like reference numerals refer to like elements throughout. The terms “exemplary” and “example” as may be used herein are not provided to convey any qualitative assessment, but instead merely to convey an illustration of an example. As used herein, terms such as “front,” “rear,” “top,” “inside,” “outside,” “inner,” “outer,” etc. are used for explanatory purposes in the examples provided below to describe the relative position of certain components or portions of components. Furthermore, as would be evident to one of ordinary skill in the art in light of the present disclosure, the terms “substantially” and “approximately” indicate that the referenced element or associated description is accurate to within applicable engineering tolerances. Thus, use of any such terms should not be taken to limit the spirit and scope of embodiments of the present invention.

According to embodiments of the present invention, an initial substrate may be used to grow a two-dimensional material comprising insulative and conductive properties, which may collectively be referred to as a two-dimensional-substrate structure. The two-dimensional-substrate structure may be applied to a target substrate comprising rigid or flexible properties via an adhesion promoter to form a lamination stack, heat and pressure may then be applied under a vacuum or controlled gas atmosphere (such as the CVD System incorporated by reference herein) to the lamination stack, and then the initial substrate may be removed from the lamination stack to form a two-dimensional-target structure. By using an initial substrate to grow the two-dimensional material rather than growing the two-dimensional material directly on the target substrate, according to embodiments of the methods and structures described herein, the two-dimensional material can be applied to target substrates having properties that are not able to support the growth process. For example, the target structure may have a lower rigidity properties and lower melting points than the initial substrate, such as may be the case when the target structure is a flexible electronic device. As such, embodiments of the present invention may allow a two-dimensional-target structure to be applied to rigid or flexible electronic devices including composite membranes; composite membranes for audio speakers and receivers; composite membrane actuators; touch screens; foldable screens; foldable touch screens; flexible, stretchable, or foldable electronic devices; flexible LEDs; flexible photovoltaics; silicon-integration of 2D devices where 2D devices are connected with circuits implemented in silicon; light sources on silicon or other wafers; photodetectors integrated with wafers; transparent electrodes on rigid or flexible glass; rigid or flexible transparent electromagnetic shielding, and other such devices known in the art, wherein the target substrate (including the two-dimensional material) may have higher conductivity over conventional two-dimensional-target structures.

A lamination stack, generally, may be understood to be the stack, or layers, of materials used in electronic devices (e.g., a lamination stack may be used to form a PCB). For example, such materials may include a conductive substrate (e.g., metal) used to grow a two-dimensional material such as graphene, hexagonal Boron Nitride (h-BN), or other such rigid or flexible and conductive materials. According to embodiments of the present invention, the lamination stack may further include the target substrate and an adhesion promoter that is used to affix the target substrate to the two-dimensional-substrate structure. The lamination stack may be heated and pressurized to secure a bond between the two-dimensional material and the target structure via the adhesion promoter. The process of heating and pressurizing may also be referred to as a lamination process. In some aspects of the present invention, heat may be applied to the base of the lamination stack (e.g., from below the lamination stack), applied to the top of the lamination stack (e.g., from a heat-source placed above the lamination stack), or applied to surround the lamination stack (e.g., similar to an oven chamber heating the lamination stack from multiple sides).

In some embodiments, the target substrate may also comprise such rigid or flexible and conductive properties as the two-dimensional material or higher rigid or flexible and conductive properties from the two-dimensional material. In recent technology, there is an increasing demand for rigid or flexible, conductive, and/or translucent materials to be used in such devices as described herein. Accordingly, there is an increased demand for efficient processes to create the materials used in these devices

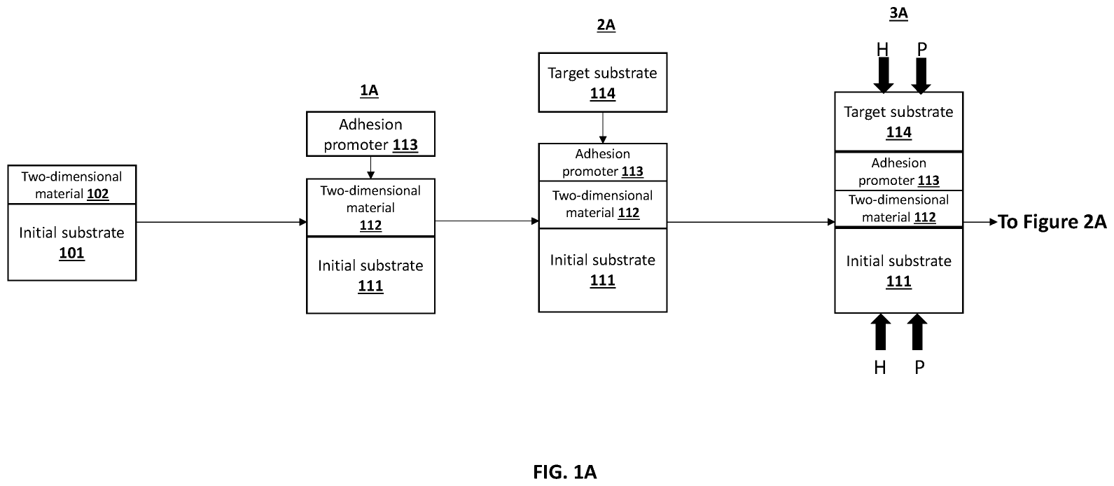

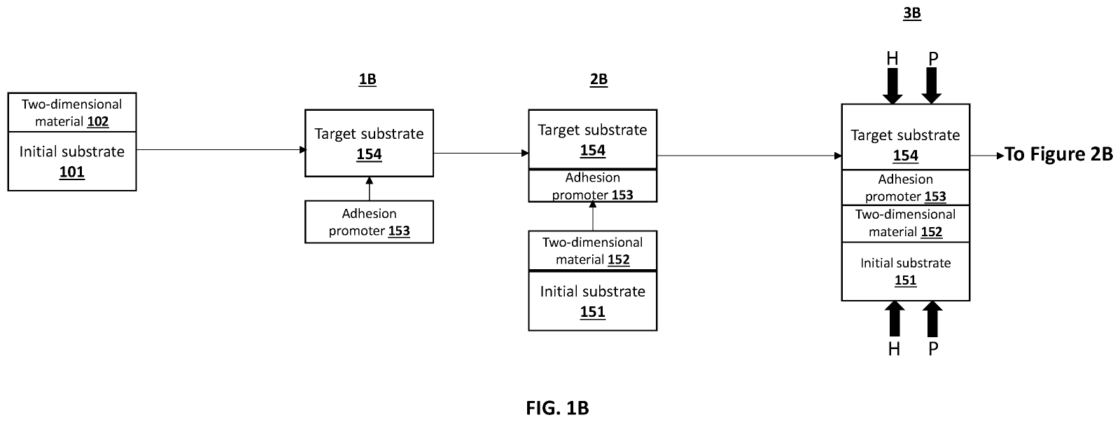

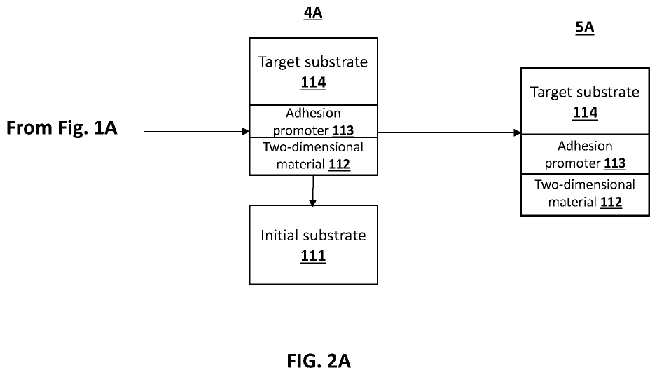

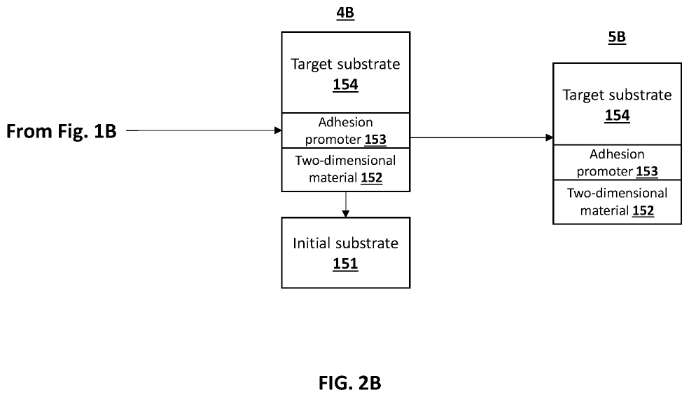

With reference to FIGS. 1A, 1B, 2A, and 2B, example methods for facilitating the creation of a lamination stack is provided in accordance with one or more embodiments of the present invention. It will be understood that each block of the block diagrams, and combinations of the blocks, may be implemented by various means. In some examples, multiple blocks (e.g., multiple initial substrates, multiple two-dimensional materials, multiple target substrates, etc.) may also be included and the process may be reiterated for each additional set of layers (e.g., for each set of initial substrates, two-dimensional materials, target substrates, and adhesion promoters). Further, the blocks of the diagram illustrated by FIGS. 1A, 1B, 2A, and 2B may, for example, be performed by an example apparatus (not pictured) to add each substrate or layer to form the lamination stack.

The method (e.g., FIGS. 1A, 1B, 2A, and 2B) may include the process of providing an initial substrate 101 that includes a two-dimensional material, such as an initial substrate on which the two-dimensional material 102 was grown using various growing methods.

In some embodiments, the two-dimensional material may be grown using such methods known in the art to grow the two-dimensional materials listed herein on the respective initial substrates. For example, to grow graphene on an initial substrate comprising metal, the methods of segregation of bulk-dissolved carbon on the initial substrate or the method of surface decomposition of carbon-containing molecules may be used to grow graphene on the initial substrates.

With respect to FIG. 1A, in some embodiments, an initial substrate 101 having the two-dimensional material 102 is provided. Next, at step 1A, an adhesion promoter 113 may be applied to the two-dimensional-substrate structure (e.g., initial substrate 111 and two-dimensional material 112). At step 2A, a target substrate 114 may be applied to the two-dimensional-substrate structure (e.g., initial substrate 111 and two-dimensional material 112) via the adhesion promoter 113 to create a lamination stack. The lamination stack may then undergo heating and pressurizing at step 3A to bond the target substrate 114 with the two-dimensional-target structure (e.g., initial substrate 111 and two-dimensional material 112) via the adhesion promoter 113. Such heat H and pressurization P may bond the substrates and materials of the lamination stack together. The method may continue as shown in FIG. 2A, where at step 4A the initial substrate 111 may be removed from the lamination stack such that only the target substrate 114 and two-dimensional material 112 are bonded via the adhesion promoter 113. Such removal of the initial substrate 111 may create the two-dimensional-target substrate shown at step 5A.

In some embodiments, the adhesion promoter may be applied to the target substrate, and the two-dimensional-substrate structure may be applied to the target substrate via the adhesion promoter, as shown in steps 1B, 2B, 3B of FIG. 1B and steps 4B and 5B of FIG. 2B. For example, once the initial substrate 101 having the two-dimension material 102 on it is provided, the process may continue to step 1B. At step 1B, an adhesion promoter 153 may be applied to a target substrate 154. At step 2B, the two-dimensional-substrate structure (e.g., initial substrate 151 and two-dimensional material 152) may be applied to the target substrate 154 via the adhesion promoter 153 to form the lamination stack. The lamination stack may undergo heating and pressurizing at step 3B to bond the target substrate 154 and the two-dimensional-substrate structure (e.g., initial substrate 151 and two-dimensional material 152) via the adhesion promoter 153. Such heat H and pressurization P may bond the substrates and materials of the lamination stack together. The method may continue as shown in FIG. 2B, where at step 4B the initial substrate 151 may be removed from the lamination stack such that only the target substrate 154 and two-dimensional material 152 are bonded via the adhesion promoter 153. Such removal of the initial substrate 111 may create the two-dimensional-target substrate shown at step 5B.

In some embodiments, the initial substrate may be removed by any number of processes depending on the materials involved (e.g., the materials used in the initial substrate and the two-dimensional material grown on the initial substrate), which is described in further detail below.

In some embodiments, the initial substrate may comprise nickel (Ni), copper (Cu), platina (Pt), cobalt (Co), chromium (Cr), iridium (Ir), manganese (Mn), iron (Fe), tungsten (W), silver (Ag), ruthenium (Ru), rhodium (Rh), palladium (Pd), gallium (Ga), indium (In), tin (Sn), or any combination thereof. In some embodiments, the initial substrate may comprise other metals known in the art which may withstand heat and/or pressure used throughout the process herein described. In some embodiments, the two-dimensional materials that may grow from the above list may comprise graphene, hexagonal Boron Nitride (h-BN), transition-metal oxide, transition-metal dichalcogenide or any other elemental/molecular analogue thereof.

In some embodiments, the initial substrate may comprise non-metallic compounds such as sapphire, fused quartz, mica, graphite, graphene, carbon, III-V compounds, II-VI compounds, silicon (Si), germanium (Ge), selenium (Se), tellurium (Te), or any combination thereof. In some embodiments, the two-dimensional materials may be grown on a substrate made from the group of compounds listed supra.

In some embodiments, the two-dimensional material grown on the initial substrate may comprise hexagonal Boron Nitride (h-BN), graphene, black phosphorus, black arsen-phosphorus, mxene, two-dimensional perovskites, or any combination thereof. In some embodiments, the two-dimensional material may comprise such combinations of materials as gallium oxide (Ga₂O₃), germanium sulfide (GaS), germanium selenide (GaSe), germanium telluride (GaTe), indium oxide (In₂O₃), indium sulfide (InS, In₂S₃), indium selenide (InSe, In₂Se₃), indium tellurium (InTe, In₂Te₃), antimony sulfide (Sb₂S₃), antimony selenide (Sb₂Se₃), antimony telluride (Sb₂Te₃), germanium oxide (GeO), germanium sulfide (GeS), germanium selenide (GeSe), germanium telluride (GeTe), stin oxide (SnOₓ), tin sulfur (SnSₓ), tin selenium (SnSeₓ), and/or tin tellurium (SnTeₓ).

In some embodiments, the two-dimensional material may comprise such combinations of materials as molybdenum disulfide (MoS₂), molybdenum diselenide (MoSe₂), molybdenum telluride (MoTe₂), tungsten disulfide (WS₂), tungsten diselenide (WSe₂), tungsten telluride (WTe₂), tin disulfide (SnS₂), tin diselenide (SnSe₂), tin telluride (SnTe₂), hafnium disulfide (HfS₂), hafnium diselenide (HfSe₂), hafnium telluride (HfTe₂), platinum disulfide (PtS₂), platinum diselenide (PtSe₂), platinum telluride (PtTe₂), titanium disulfide (TiS₂), titanium diselenide (TiSe₂), titanium telluride (TiTe₂), rhenium disulfide (ReS₂), rhenium diselenide (ReSe₂), or rhenium telluride (ReTe₂).

In some embodiments, the two-dimensional material grown on the initial substrate listed supra, which may comprise such materials as bismuth (Bi), antimony (Sb), tin (Sn), oxygen (O), sulfur (S), selenium (Se), tellurium (Te), or any combination thereof. In some embodiments, the two-dimensional material may comprise such combinations of materials as bismuth(III) oxide (Bi₂O₃), bismuth sulfide (Bi₂S₃), bismuth(III) selenide (Bi₂Se₃), bismuth telluride (Bi₂Te₃), antimony(III) oxide (Sb₂O₃), antimony sulfide (Sb₂S₃), antimony triselenide (Sb₂Se₃), antimony telluride (Sb₂Te₃), tin(II) oxide (Sn₂O₃), tin(II) sulfide (Sn₂S₃), tin(II) sulfide (Sn₂Se₃), or tin(II) telluride (Sn₂Te₃).

In some embodiments, the adhesion promoter used in the present invention may comprise hydrocarbon-based thin film adhesive, epoxy resin, polyester, silicone, rubber, polysulfides, polypropylene, polyethylene, polyurethane, polydimethylsiloxane (PDMS), polyimide (PI), parylene, polyetherimide (PEI), polyamide (PA), polylactic acid (PLA), kapton, self-assembled monolayer (SAM), parylen, polyvinyl alcohol PVA, polystyrene PS, polycarbonate (PC), cellulose acetate (CA), ethylene vinyl acetate (EVA), hexagonal Boron-Nitride (h-BN), or any combination thereof.

In some embodiments, the target substrate may comprise polydimethylsiloxane polyethylene terephthalate (PET), polydimethylsiloxane (PDMS), polytetrafluoroethylene (PTFE), low density polyethylene (LDPE), nylon, poly(vinylpyrrolidone) (PVP), polystyrene (PS), poly(methyl methacrylate) (PMMA), poly(vinyl alcohol) (PVA), poly(vinyl chloride) (PVC), poly(vinylidene fluoride) (PVDF), polyalactic acid (PLA), polyimide (PI), polyetherimide (PEI), polyamide (PA), acrylonitrile butadiene styrene (ANBS), styrenic resins (e.g., ABS, ASA, SMA), kapton, silicon (Si), silicon dioxide (SiO2), thin-film metal-oxide, or any combination thereof.

In some embodiments, the target substrate may comprise at least a semiconductor wafer or other solid wafer. In some embodiments, the semiconductor wafer (e.g., target substrate) may further comprise silicon (Si), germanium (Ge), II-VI compound, III-V compound, glass, sapphire, quartz, or any combination thereof.

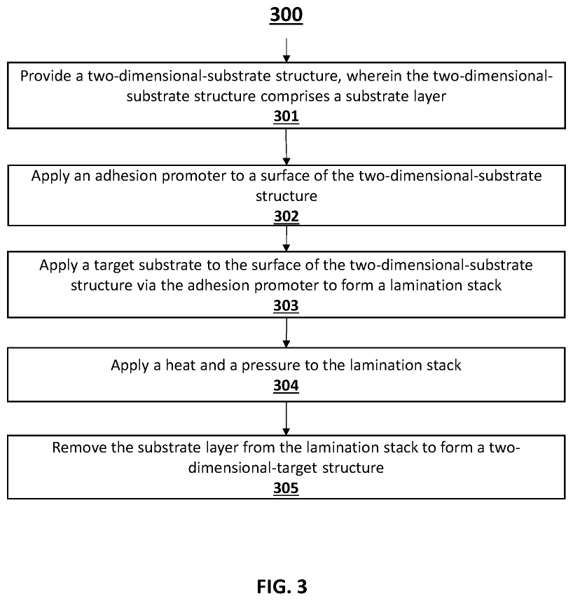

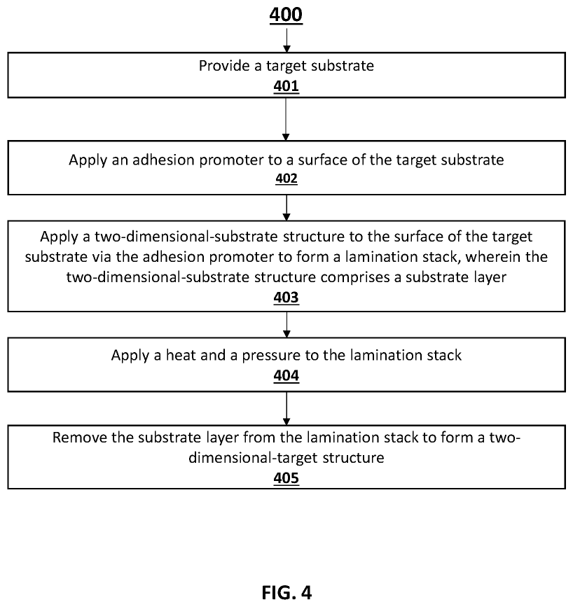

FIG. 3 is a flowchart providing an example method 300 for facilitating the process of applying a two-dimensional material to a target substrate, via the application of an adhesion promoter to the two-dimensional-substrate structure, and removing the initial substrate on which the two-dimensional material was grown, in accordance with one or more embodiments of the present invention. FIG. 4 is a flowchart providing an example method 400 for facilitating the process of applying a two-dimensional-substrate structure to a target substrate, via the application of an adhesion promoter to the target substrate, and removing the initial substrate on which the two-dimensional material was grown, in accordance with one or more embodiments of the present invention. It will be understood that each combination of blocks in the flowcharts may be implemented by various means. In some example embodiments, certain ones of the operations herein may be modified or further amplified as described below. Moreover, in some embodiments, additional optional operations may also be included. It should be appreciated that each of the modifications, optional additions, or amplifications described herein may be included with the operations herein either alone or in combination with any others among the features described herein. The operations illustrated in FIGS. 3 and 4 may, for example, be performed by an example apparatus (such as the CVD System incorporated by reference herein) to add each material or layer, or remove each material or layer (e.g., initial substrate, two-dimensional material, adhesion promoter, target substrate, etc.) to form the two-dimensional-target structure.

The method (e.g., method 300) may include the step of providing a two-dimensional-substrate structure, wherein the two-dimensional-substrate comprises a substrate layer (i.e., initial substrate layer), at step 301. As described above with reference to FIG. 1A, the two-dimensional material may be grown on the initial substrate to form the two-dimensional-substrate structure. At step 302, an adhesion promoter may be applied to the surface of the two-dimensional-substrate structure such that at step 303 a target substrate may be applied to the two-dimensional-substrate structure via the adhesion promoter to form a lamination stack. At step 304, heat and pressure (e.g., the process of laminating) may be applied to the lamination stack. After the lamination process has occurred at step 304, the initial substrate layer from the lamination stack (e.g., the initial substrate layer from the two-dimensional-substrate structure) may be removed from the lamination stack to form a two-dimensional-target structure at step 305.

With reference to FIG. 4, a method (e.g., method 400) is provided for facilitating the process of applying a two-dimensional-substrate structure to a target substrate, via the application of an adhesion promoter to the target substrate, and removing the initial substrate on which the two-dimensional material was grown, in accordance with one or more embodiments of the present invention.

The method (e.g., method 400) may include the step of providing a target substrate at step 401. At step 402, an adhesion promoter may be applied to a surface of the target substrate. The two-dimensional-substrate structure (previously grown) may be applied to the target substrate via the adhesion promoter to form the lamination stack at step 403, wherein the two-dimensional-substrate structure comprises an initial substrate layer. As described above with reference to FIG. 1B, the two-dimensional material may be grown on the initial substrate to form the two-dimensional-substrate structure. Likewise, at step 404, heat and pressure (e.g., the process of laminating) may be applied to the lamination stack. After the lamination process has occurred at step 404, the initial substrate layer from the lamination stack (e.g., the initial substrate layer from the two-dimensional-substrate structure) may be removed from the lamination stack to form a two-dimensional-target structure at step 405.

In some embodiments, the initial substrate—post-lamination—may be removed via a process of metal etching of the initial substrate with certain metal etchants. For example, if the initial substrate comprises copper (Cu), then a copper etchant may be used to remove the initial substrate from the two-dimensional material. Similarly, if using nickel as an initial substrate, then a nickel etchant may be used. It may be understood by one of skill in the art, that each of the initial substrates listed herein may comprise different metal etchants.

In some embodiments, the initial substrate may be removed—post-lamination—via a process of applying a sacrificial substrate layer, further comprising transition metal dichalcogenide (TMDC) on a silicon/silicon dioxide substrate (Si/SiO₂). In some embodiments, the two-dimensional material may comprise the TMDC and the initial substrate may comprise Si/SiO₂. In some embodiments, the Si/SiO₂ may be etched using known methods in the art at the time of this application. A sacrificial layer (e.g., an initial substrate such as nickel) may be used to grow the graphene, then the sacrificial layer (e.g., nickel) with the two-dimensional material may be transferred and attached to a target substrate such that the two-dimensional material is between the target substrate and the initial layer. Once the two-dimensional material has been attached to the target substrate, the initial layer may be etched from to expose a surface of the two-dimensional material (e.g., the surface previously occupied by the initial substrate).

In some embodiments, the two-dimensional materials may be grown on oxide materials comprising sapphire, and SiO₂. For those oxide materials, further including the two-dimensional material grown on the oxide materials, the process to remove the initial substrate (e.g., oxide material) may comprise an interfacial removal by water absorption between a hydrophobic and hydrophilic interface. Such hydrophobic materials may comprise those materials that are repellant to water which comprise a contact angle of greater than 90 degrees (e.g., graphene). In contrast, hydrophilic materials may comprise those materials that are repellant to water, which comprise a contact angel of lesser than 90 degrees (e.g., sapphire, SiO₂). In such interfacial removal processes via water absorption, water in liquid state or gaseous state (e.g., bubbles) may be applied to the lamination structure to separate the initial substrate from the two-dimensional material.

Many modifications and other embodiments of the present inventions set forth herein will come to mind to one skilled in the art to which these inventions pertain having the benefit of the teachings presented in the foregoing descriptions and the associated drawings. Therefore, it is to be understood that the present inventions are not to be limited to the specific embodiments disclosed and that modifications and other embodiments are intended to be included within the scope of the appended claims. Moreover, although the foregoing descriptions and the associated drawings describe example embodiments in the context of certain example combinations of elements and/or functions, it should be appreciated that different combinations of elements and/or functions may be provided by alternative embodiments without departing from the scope of the appended claims. In this regard, for example, different combinations of elements and/or functions than those explicitly described above are also contemplated as may be set forth in some of the appended claims. Although specific terms are employed herein, they are used in a generic and descriptive sense only and not for purposes of limitation.

1. A method of applying a two-dimensional material to a target substrate comprising:
providing a target substrate;
applying an adhesion promoter to a surface of the target substrate;
applying a two-dimensional-substrate structure to the surface of the target substrate via the adhesion promoter to form a lamination stack, wherein the two-dimensional-substrate structure comprises an initial substrate layer and a two-dimensional material on at least one of a top surface of the initial substrate layer or a bottom surface of the initial substrate layer;
applying a heat and a pressure to the lamination stack; and
removing the initial substrate layer from the lamination stack, after the heat and the pressure are applied, to form a two-dimensional-target structure.

2. The method of claim 1, further comprising applying a heat and a pressure to the two-dimensional-target structure.

3. The method of claim 1, wherein the two-dimensional material comprises hexagonal Boron Nitride (h-BN), graphene, black phosphorus, black arsen-phosphorus, mxene, two-dimensional perovskites, or any combination thereof.

4. The method of claim 1, wherein the adhesion promoter layer comprises epoxy resin, polyester, silicone, rubber, polysulfides, polypropylene, polyethylene, polyurethane, polydimethylsiloxane (PDMS), polyimide (PI), parylene, polyetherimide (PEI), polyamide (PA), polylactic acid (PLA), hydrocarbon-based film adhesive, Kapton, self-assembled monolayer (SAM), parylen, polyvinyl alcohol PVA, Polystyrene PS, Polycarbonate (PC), cellulose acetate (CA), ethylene vinyl acetate (EVA), or any combination thereof.

5. The method of claim 1, wherein the initial substrate layer comprises nickel (Ni), copper (Cu), platina (Pt), cobalt (Co), chromium (Cr), iridium (Ir), manganese (Mn), iron (Fe), tungsten (W), silver (Ag), ruthenium (Ru), rhodium (Rh), gold (Au), molybdenum (Mo), palladium (Pd), gallium (Ga), Indium (In), tin (Sn), silicon (Si), silicon dioxide (SiO2), mica, sapphire, polymeric liquid glass, glass substrate, AI2O3 metals, hafnium, or any combination thereof.

6. The method of claim 1, wherein the target substrate comprises at least a semiconductor or other solid wafer.

7. The method of claim 6, wherein the semiconductor wafer comprises silicon (Si), germanium (Ge), II-VI compound, III-V compound, glass, sapphire, quartz, or any combination thereof.

8. The method of claim 1, wherein the target substrate comprises a polymer.

9. The method of claim 8, wherein the polymer comprises polyethylene terephthalate (PET), polydimethylsiloxane (PDMS), polytetrafluoroethylene (PTFE), low density polyethylene (LDPE), nylon, ply(vinylpyrrolidone) (PVP), polystyrene (PS), poly(methyl methacrylate) (PMMA), poly(vinyl alcohol) (PVA), poly(vinyl chloride) (PVC), poly(vinylidene fluoride) (PVDF), polyalactic acid (PLA), polyimide (PI), polyetherimide (PEI), polyamide (PA), acrylonitrile butadiene styrene (ANBS), styrenic resins, kapton, silicon (Si), silicon dioxide (SiO2), thin-film metal-oxide, or any combination thereof.

10. A method of applying a two-dimensional material to a target substrate comprising:
providing a two-dimensional-substrate structure, wherein the two-dimensional-substrate structure comprises an initial substrate layer and a two-dimensional material on at least one of a top surface of the initial substrate layer or a bottom surface of the initial substrate layer;
applying an adhesion promoter to a surface of the two-dimensional-substrate structure;
applying a target substrate to the surface of the two-dimensional-substrate structure via the adhesion promoter to form a lamination stack;
applying a heat and a pressure to the lamination stack; and
removing the initial substrate layer from the lamination stack, after the heat and the pressure are applied, to form a two-dimensional-target structure.

11. The method of claim 10, further comprising applying a heat and a pressure to the two-dimensional-target structure.

12. The method of claim 10, wherein the two-dimensional material comprises hexagonal Boron Nitride (h-BN), graphene black phosphorus, black arsen-phosphorus, mxene, two-dimensional perovskites, or any combination thereof.

13. The method of claim 10, wherein the adhesion promoter layer comprises epoxy resin, polyester, silicone, rubber, polysulfides, polypropylene, polyethylene, polyurethane, polydimethylsiloxane (PDMS), polyimide (PI), parylene, polyetherimide (PEI), polyamide (PA), polylactic acid (PLA), hydrocarbon-based film adhesive, Kapton, self-assembled monolayer (SAM), parylen, polyvinyl alcohol PVA, Polystyrene PS, Polycarbonate (PC), cellulose acetate (CA), ethylene vinyl acetate (EVA), or any combination thereof.

14. The method of claim 10, wherein the initial substrate layer comprises nickel (Ni), copper (Cu), platina (Pt), cobalt (Co), chromium (Cr), iridium (Ir), manganese (Mn), iron (Fe), tungsten (W), silver (Ag), ruthenium (Ru), rhodium (Rh), gold (Au), molybdenum (Mo), palladium (Pd), gallium (Ga), Indium (In), tin (Sn), silicon (Si), silicon dioxide (SiO2), mica, sapphire, polymeric liquid glass, glass substrate, AI2O3 metals, hafnium, or any combination thereof.

15. The method of claim 10, wherein the target substrate comprises at least a semiconductor wafer or other solid wafer.

16. The method of claim 15, wherein the semiconductor wafer comprises silicon (Si), germanium (Ge), II-VI compound, III-V compound, glass, sapphire, quartz, or any combination thereof.

17. The method of claim 10, wherein the target substrate comprises a polymer.

18. The method of claim 17, wherein the polymer comprises polyethylene terephthalate (PET), polydimethylsiloxane (PDMS), polytetrafluoroethylene (PTFE), low density polyethylene (LDPE), nylon, ply(vinylpyrrolidone) (PVP), polystyrene (PS), poly(methyl methacrylate) (PMMA), poly(vinyl alcohol) (PVA), poly(vinyl chloride) (PVC), poly(vinylidene fluoride) (PVDF), polyalactic acid (PLA), polyimide (PI), polyetherimide (PEI), polyamide (PA), acrylonitrile butadiene styrene (ANBS), styrenic resins, or any combination thereof.

19. A two-dimensional-target structure formed by the process comprising the steps of:
providing a target substrate;
applying an adhesion promoter to a surface of the target substrate;
applying a two-dimensional-substrate structure to the surface of the target substrate via the adhesion promoter to form a lamination stack, wherein the two-dimensional-substrate structure comprises an initial substrate layer and a two-dimensional material on at least one of a top surface of the initial substrate layer or a bottom surface of the initial substrate layer;
applying a heat and a pressure to the lamination stack; and
removing the initial substrate layer from the lamination stack, after the heat and the pressure are applied, to form a two-dimensional-target structure.
